(19) United States
(12) Patent Application Publication
(10) Pub. No.: US 2016/0289814 A1
(43) Pub. Date: Oct. 6, 2016

(54) DEPOSITION APPARATUS

(71) Applicant: SAMSUNG DISPLAY CO., LTD., Yongin-City (KR)

(72) Inventor: Jeong Won HAN, Seongnam-si (KR)

(21) Appl. No.: 15/009,873

(22) Filed: Jan. 29, 2016

(30) Foreign Application Priority Data
Mar. 31, 2015 (KR) 10-2015-0045313

(51) Int. Cl. C23C 14/04; C23C 14/24

(52) U.S. Cl. CPC C23C 14/042; C23C 14/24

(57) ABSTRACT

A deposition apparatus includes a chamber maintaining a vacuum atmosphere, a deposition material container within the chamber, the deposition material container containing a deposition material, a substrate fixing part that faces the deposition material container to fix a substrate, a mask fixing part on a first surface of the substrate, the mask fixing part including a plurality of magnets on the first surface of the substrate, a driving cam unit that reciprocates along a first direction, a following cam unit that reciprocates in a second direction crossing the first direction in accordance with a reciprocation direction of the driving cam unit, and a driving motor to supply a predetermined power to the driving cam unit, and a mask on a second surface of the substrate attachable to the substrate by a magnetic force of the plurality of magnets.

### CROSS-REFERENCE TO RELATED APPLICATION

Korean Patent Application No. 10-2015-0045313, filed on Mar. 31, 2015, in the Korean Intellectual Property Office, and entitled: “Deposition Apparatus,” is incorporated by reference herein in its entirety.

### BACKGROUND

1. Field

The present disclosure relates to a deposition apparatus that may be used regardless of the sizes of a substrate and a mask.

2. Description of the Related Art

Recently, with the development of display technologies, display techniques have been applied to large-sized electronic products in addition to small-sized electronic products. Generally, a display device converts electronic information into a visually recognizable form to a human. Examples of display devices include various devices, e.g., an organic light emitting diode display, a liquid crystal display, and a plasma display device.

A deposition process that vaporizes materials, e.g., metal, to form a thin film has been used to manufacture these display devices. The deposition process may be mainly used to form a thin film transistor, a circuit, or a component, e.g., an emission layer of a display device. To perform the deposition process of a thin film, a mask opened in an area corresponding to an area of the thin film is disposed on a substrate, and then a material to be deposited on the substrate is vaporized under a vacuum atmosphere.

### SUMMARY

The present disclosure provides a deposition apparatus that may be used regardless of the sizes of a substrate and a mask.

An exemplary embodiment provides a deposition apparatus, including a chamber maintaining a vacuum atmosphere, a deposition material container within the chamber, the deposition material container containing a deposition material, a substrate fixing part that faces the deposition material container to fix a substrate, a mask fixing part on a first surface of the substrate, the mask fixing part including a plurality of magnets on the first surface of the substrate, a driving cam unit that reciprocates along a first direction, a following cam unit that reciprocates in a second direction crossing the first direction in accordance with a reciprocation direction of the driving cam unit, and a driving motor to supply a predetermined power to the driving cam unit, and a mask on a second surface of the substrate attachable to the substrate by a magnetic force of the plurality of magnets.

The driving cam unit may include a driving cam plate including a plurality of through-holes disposed along the first direction; a driving camshaft reciprocating along the first direction by directly receiving a predetermined power from the driving motor; and driving cam followers through which the driving camshaft passes, disposed in a plurality along the driving camshaft, and the reciprocating motion of which depends on the reciprocation direction of the driving camshaft.

The following cam unit may include a following cam plate, of which each of the plurality of magnets is fixed to one surface thereof and is reciprocating along the second direction corresponding to the reciprocation direction of the driving cam unit; a first following cam follower disposed to have an angle of about 0 to 90 degrees from the first direction toward the second direction; and a second following cam follower passing through the through-hole to fix the first following cam follower to the following cam plate.

A width of a direction parallel to the first direction of the through-hole may be equal to a width of a direction parallel to the first direction of the second following cam follower, and a width of a direction parallel to the second direction of the through-hole may be greater than that of a direction parallel to the second direction of the second following cam follower.

The driving cam unit may include a pair of driving cam guides disposed along the first direction to guide the reciprocation of the driving cam follower.

The driving cam plate may include a fixing ring which the driving camshaft is inserted into, passes through, and is fixed to, and a shaft guide into which the fixing ring is inserted to be combined with the driving cam plate.

An insertion hole in which one end of the driving camshaft is inserted may be formed in the driving motor, a first screw thread may be formed on the one end of the driving camshaft inserted into the insertion hole, and a second screw thread may be formed to correspond to the first screw thread on an interior circumference of the insertion hole, wherein when the driving motor rotates the insertion hole, the first screw thread and the second screw thread perform a screwing movement, and the driving camshaft may reciprocate according to the screw movement.

The following cam plate may include a magnet fixing groove formed along the first direction, and the magnet may be inserted and fixed to the magnet fixing groove.

The mask may include an active area opened to correspond to a deposition area in which the deposition material is deposited on the substrate; and a non-active area blocking the deposition material from being deposited on the substrate.

Each of the driving cam unit and the following cam unit may be provided in a plurality, and the pluralities of the driving cam units and the following cam units may be respectively integrally combined to be disposed parallel at a position corresponding to the non-active area of the mask in order to have an interval corresponding to the active area of the mask.

Magnetic poles of neighboring magnets may be arranged opposite from each other.

### BRIEF DESCRIPTION OF THE DRAWINGS

Features will become apparent to those of ordinary skill in the art by describing in detail exemplary embodiments with reference to the attached drawings, in which:

FIG. 1 illustrates a schematic diagram of a deposition apparatus according to an exemplary embodiment.

FIG. 2 illustrates a perspective view of a mask fixing part according to an exemplary embodiment.

FIG. 3 illustrates a perspective view of a driving cam unit and a following cam unit coupled according to an exemplary embodiment.

FIG. 4 illustrates an enlarged view of the dotted line portion of FIG. 3.

FIG. 5 illustrates a perspective view of a driving cam plate according to an exemplary embodiment.

FIG. 6 illustrates a bottom view of the coupled driving cam unit and following cam unit of FIG. 3.

FIG. 7 illustrates a perspective view of a driving cam follower according to an exemplary embodiment.

FIG. 8 illustrates a perspective view of a driving camshaft inserted into a plurality of driving cam followers according to an exemplary embodiment.

FIG. 9 illustrates an enlarged view of the dotted line portion of FIG. 8.

FIG. 10 illustrates a perspective view of a following cam unit according to an exemplary embodiment.

FIG. 11 illustrates an enlarged view of the dotted line portion of FIG. 10.

FIG. 12 illustrates a schematic view of a driving cam unit reciprocating in a first direction according to an exemplary embodiment.

FIG. 13 illustrates a schematic view of a following cam unit reciprocating in a second direction according to an exemplary embodiment.

FIG. 14 illustrates a perspective view of a driving cam guide according to an exemplary embodiment.

FIG. 15 illustrates a cross-sectional view of a driving camshaft inserted into a driving motor according to an exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

A deposition apparatus 1000 according to an exemplary embodiment will now be described with reference to the accompanying drawings.

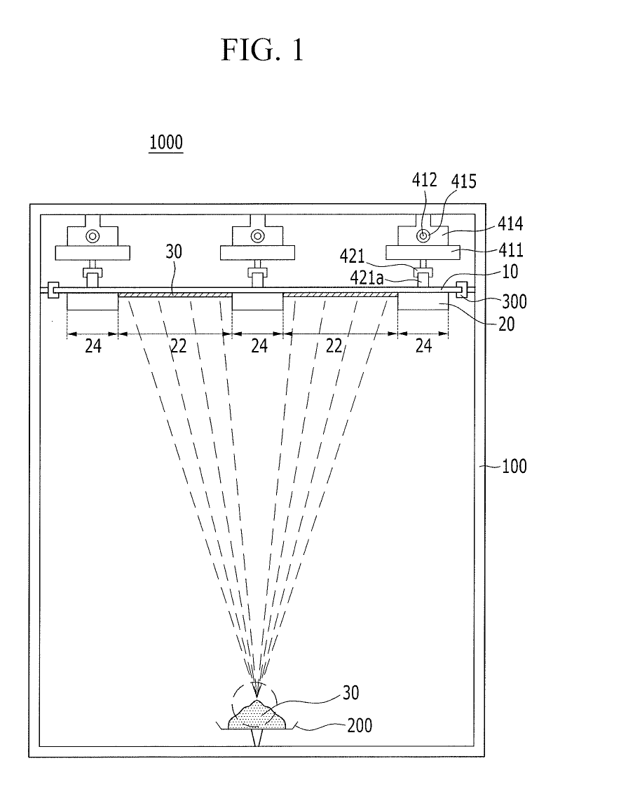

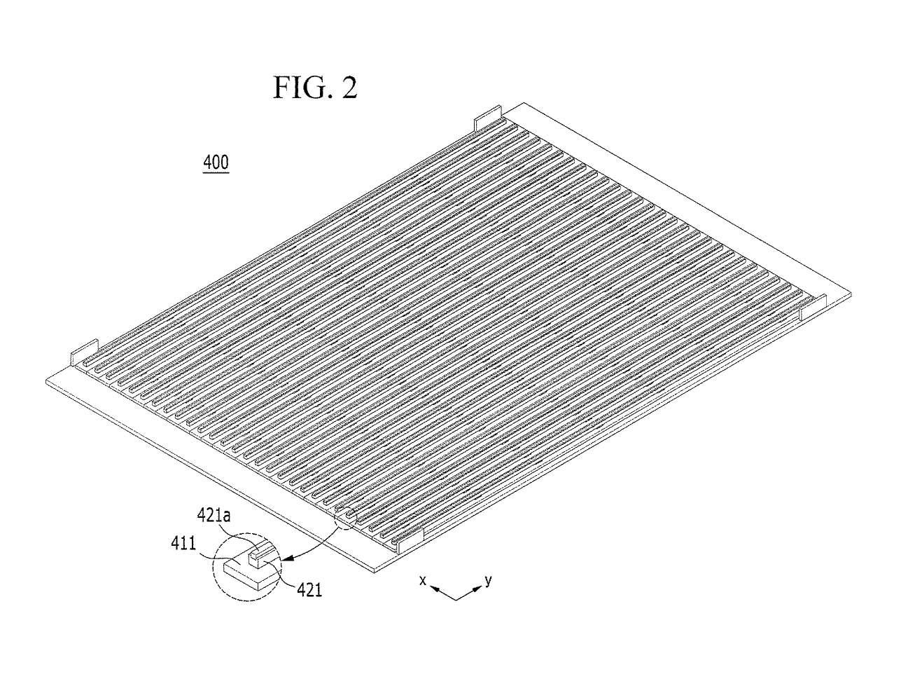

FIG. 1 is a schematic diagram of a deposition apparatus according to an exemplary embodiment, and FIG. 2 is a perspective view of a mask fixing part according to an exemplary embodiment.

As shown in FIG. 1, a deposition apparatus 1000 according to an exemplary embodiment may include a chamber 100, a deposition material container 200, a substrate fixing part 300, and a mask fixing part 400.

The chamber 100 has an inside that is in vacuum atmosphere, e.g., an interior of the chamber 100 is at vacuum atmosphere, and it includes a housing that may be blocked from the outside. A deposition material 30 is deposited inside the chamber 100.

Herein, the “vacuum atmosphere” does not mean only the state in which no material is present in the chamber, but may mean a state approaching a vacuum and may mean a state in which inert gas is injected into the chamber to reduce a pressure difference with respect to the outside, e.g., exterior of the chamber 100. The “vacuum atmosphere” of the present disclosure may include any deposition environment in which the possible occurrence of other chemical reactions other than the deposition, while the deposition material 30 is evaporated, may be excluded.

The deposition material container 200 is disposed within the chamber 100, and is a part in which the deposition material 30 is contained and vaporized. The deposition material container 200 according to the exemplary embodiment may be made of a ceramic material having strong resistance against heat and chemical reactions, e.g., a furnace, but is not limited thereto. Therefore, any container made of a material that may contain the deposition material 30 without reacting with the deposition material 30 even at high temperature may be included in the scope of the present disclosure.

The deposition material 30 may be metal, and may include metal oxide, e.g., indium tin oxide (ITO). In addition, any kind of material that needs to be formed as the thin film on a substrate 10 may be used, and accordingly, the scope of the present disclosure is not limited by a kind of deposition material 30.

As shown in FIG. 1, the substrate fixing part 300 is disposed at a position opposite to the deposition material container 200 within the chamber 100. Thus, the deposition material 30 vaporized from the deposition material container 200 may be smoothly deposited. The substrate fixing part 300 is formed in a jig form, e.g., to fix the substrate 10, while the deposition process is performed.

In FIG. 1, the exemplary embodiment illustrates the substrate fixing part 300 in a jig form, but is not limited thereto. The substrate fixing part 300 according to various exemplary embodiments disposes the substrate 10 on a plate, and fixes the substrate 10 by an intake scheme using an intake apparatus, or the like.

The substrate 10 fixed to the substrate fixing part 300 according to the present exemplary embodiment may be made of, e.g., glass and plastic. The substrate 10 may be made of a rigid material or a flexible material.

The mask fixing part 400 is disposed on a first surface of the substrate 10 and includes a plurality of magnets 421a, e.g., the plurality of magnets 421a may be spaced apart from each other and contact the first surface of the substrate 10. The mask fixing part 400 will be described in more detail below.

A mask 20 is disposed on a second surface of the substrate 10, i.e., on a surface opposite the first surface of the substrate 10, and the mask 20 according to the present exemplary embodiment may be made of a material that may be fixed by a magnetic force of the magnets 421a of the mask fixing part 400. Accordingly, the mask 20 according to the present exemplary embodiment may mainly be a metal material, but any other non-metal material that can be fixed by a magnetic force may be used as the mask 20 according to the present exemplary embodiment.

In this case, the mask 20 includes an active area 22 opened to correspond to a deposition area formed for the deposition material to be deposited on the substrate 10, and a non-active area 24 that is blocked to prevent the deposition material from being deposited on the substrate. For example, as illustrated in FIG. 1, the magnets 421a of the mask fixing part 400 may correspond to the non-active area 24, e.g., the magnets 421a may overlap the non-active area 24, so the magnets 421a may fix, e.g., and hold, the non-active area 24 to the substrate 10 by the magnetic force. For example, as illustrated in FIG. 1, the active and non-active areas 22 and 24 of the mask 20 may be alternately arranged on the second surface of the substrate 10, so the deposition material 30 from the deposition material container 200 may be deposited on the second surface of the substrate 10 through the active area 22 of the mask 20.

As the position where a deposition area is formed may change depending on the size and use of a substrate, the active area 22 and the non-active area 24 of the same mask 20 according to example embodiments may be changed to correspond to the changing deposition position. For example, the active area 22 and the non-active area 24 of the same mask 20 according to example embodiments may vary, in accordance with adjustment, e.g., movement, of the magnets 421a of the mask fixing part 400 in order to account for varying sizes and positions of a desired deposition area. In contrast, a conventional mask has to be changed to account for varying sizes of a substrate, or a separate deposition apparatus has to be used.

In detail, the deposition apparatus 1000 according to the present exemplary embodiment variably adjusts an interval between the magnets 421a of the mask fixing part 400 fixing the mask 20 to correspond to an interval between the active area 22 and the non-active area 24. For example, the interval between two adjacent magnets 421a (e.g., in the horizontal direction of FIG. 1) may be increased or decreased, in order to adjust corresponding distances between adjacent non-active area 24 (e.g., in the horizontal direction of FIG. 1), thereby adjusting the sizes and positions of the active areas 22 of the mask 20.

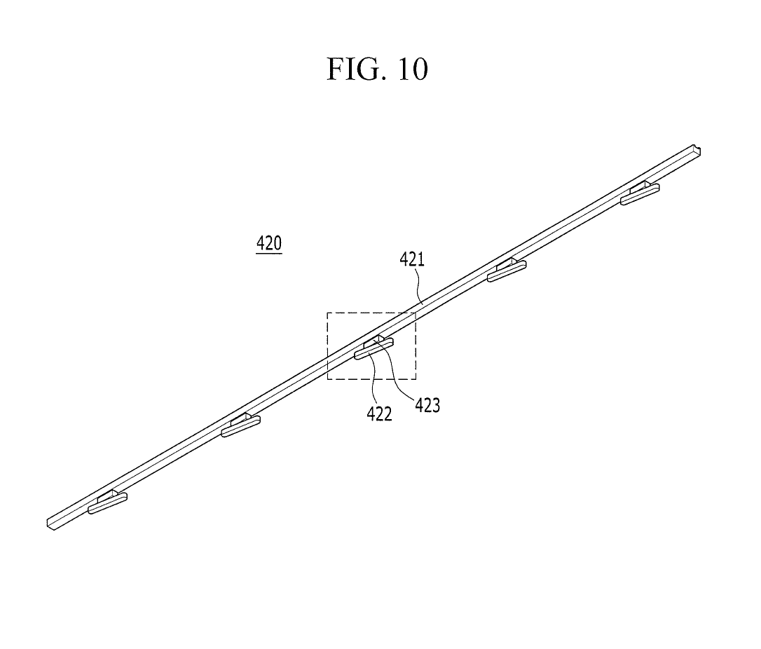

Referring to FIG. 2, the deposition apparatus 1000 that variably adjusts the interval between the magnets 421a may do so via the mask fixing part 400. The mask fixing part 400 may include a driving cam unit 410, a following cam unit 420 (FIG. 10), and a driving motor 430 (FIG. 15). As illustrated in FIGS. 1-2, the mask fixing part 400 may be attached to the first surface of the substrate 10, such that the magnets 421a of the mask fixing part 400 are facing the first surface of the substrate 10. Processes in which the mask fixing part 400 including the driving cam unit 410, the following cam unit 420, and the driving motor 430 adjusts the interval according to an exemplary embodiment will now be described in detail.

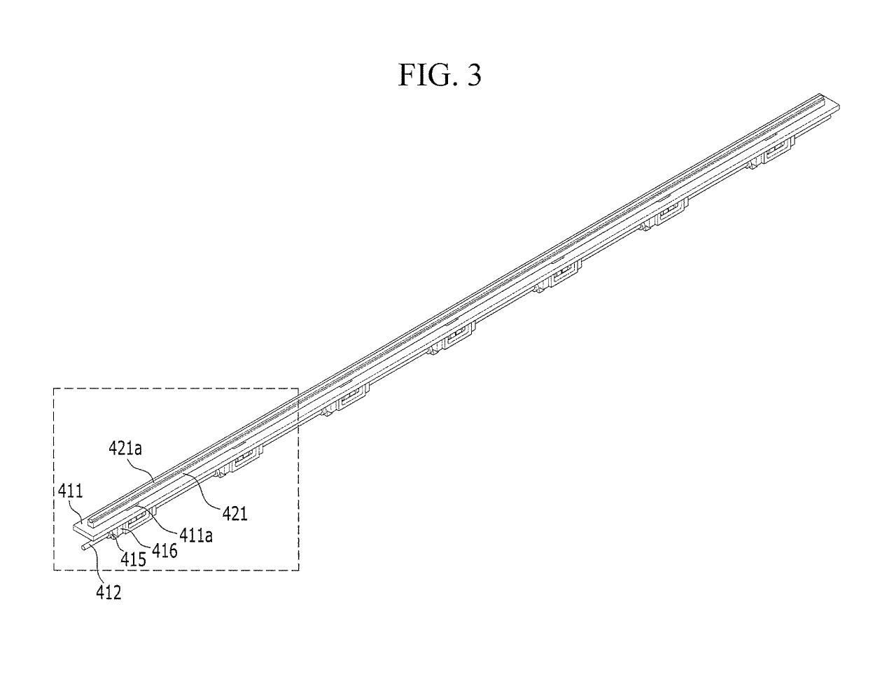

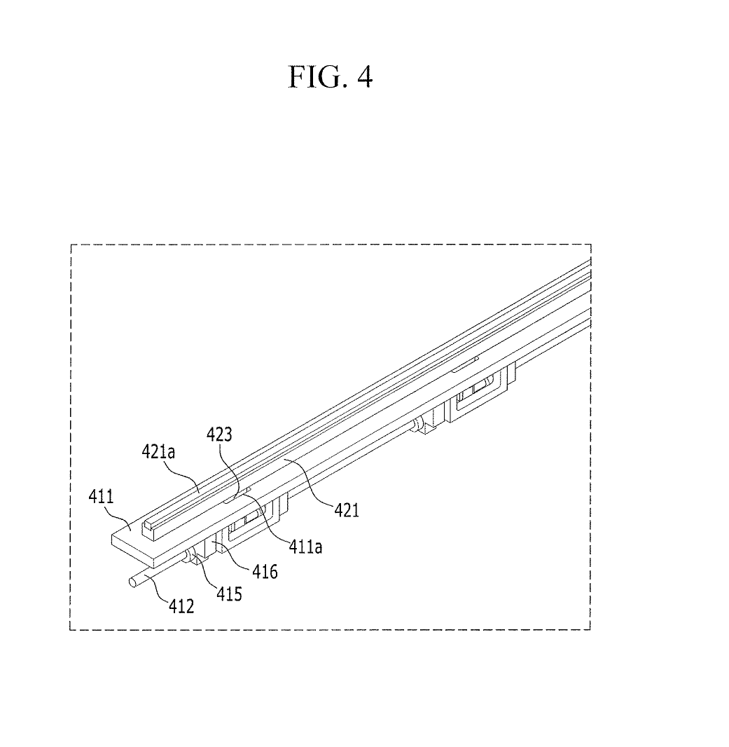

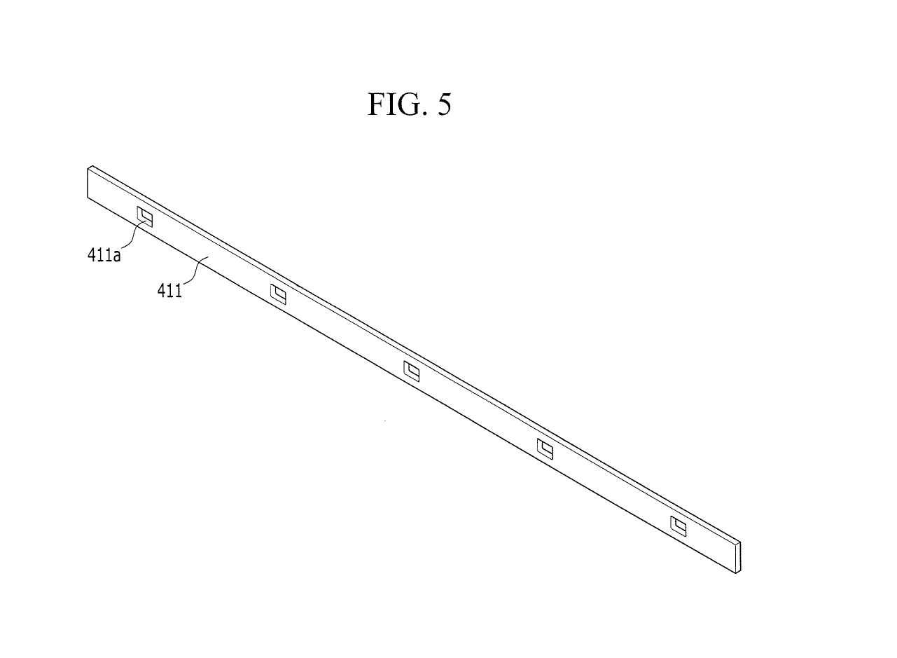

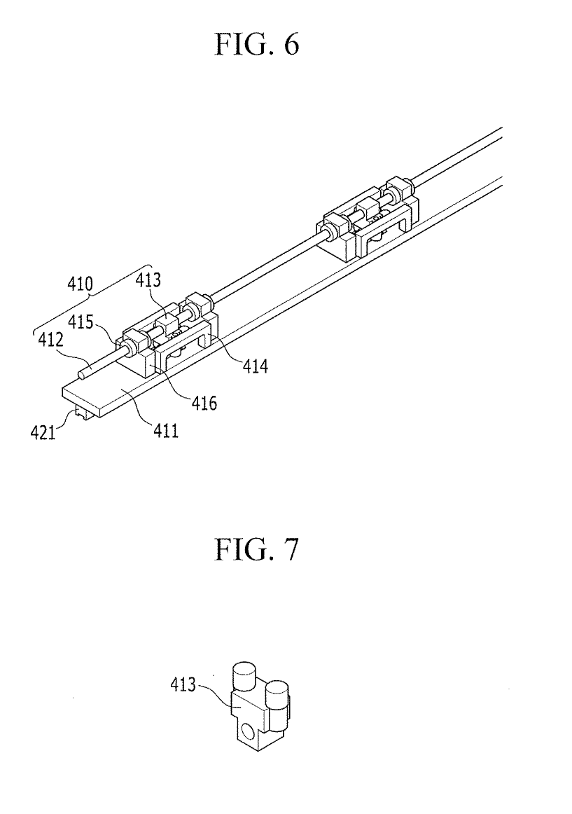

FIG. 3 illustrates a perspective view of the driving cam unit 10, FIG. 4 illustrates an enlarged view of the dotted line portion of FIG. 3, FIG. 5 illustrates a perspective view of a driving cam plate 411, and FIG. 6 illustrates a bottom view of the coupled driving cam unit 410 and following cam unit 420.

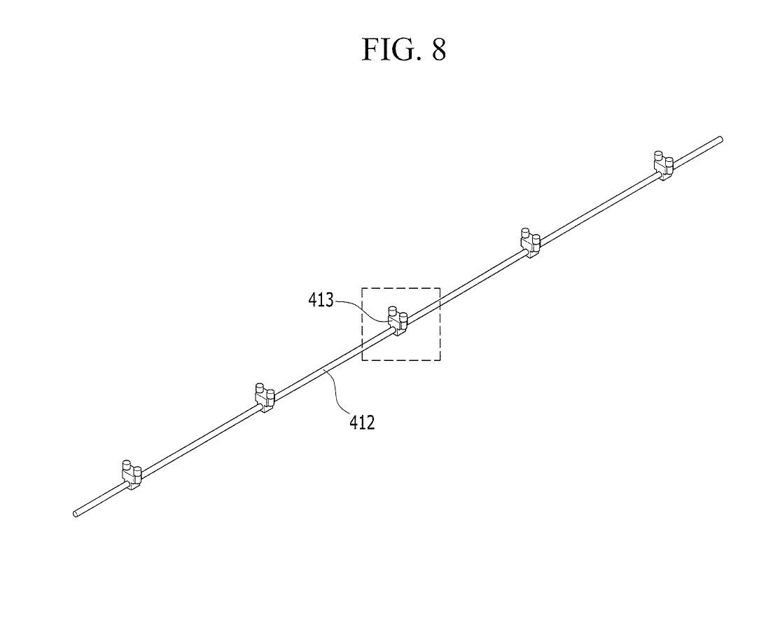

Referring to FIG. 3-4, the driving cam unit 410 reciprocates, e.g., moves, by receiving power along a first direction. The power that reciprocates the driving cam unit 410 may be supplied from the driving motor 430 that will be described later. The driving cam unit 410, as shown in FIGS. 3-6, may include the driving cam plate 411, a driving camshaft 412, a driving cam follower 413 (FIG. 8), a fixing ring 415, and a shaft guide 416.

Referring to FIGS. 4-5, the driving cam plate 411 includes a plurality of through-holes 411a, and it is a bar-shaped plate disposed along the first direction. The driving cam plate 411 may not move, but is fixed even while the driving cam unit 410 reciprocates along the first direction. Accordingly, the driving cam plate 411 relatively assists in the movements of other components, and serves to be the basis of the movements of other components.

Referring to FIGS. 3-4, the driving camshaft 412 is directly connected to the driving motor 430, to be described later, in order to directly receive the power from the driving motor 430. Therefore, the driving camshaft 412 actually reciprocates, e.g., moves, along the first direction.

Referring to FIG. 6, the fixing ring 415 has a ring-shaped structure that the driving camshaft 412 is inserted into, passes through, and then is fixed to. The driving camshaft 412 may pass through the fixing ring 415 to reciprocate along the first direction.

The shaft guide 416 is directly combined with the driving cam plate 411, and the fixing ring 415 may be disposed to be spaced apart from the driving cam plate 411 by a predetermined distance according to the height of the shaft guide 416. As described above, the driving camshaft 412 is inserted in and passes through the fixing ring 415, which is disposed to be spaced apart from the driving cam plate 411 by the shaft guide 416 in order for the fixing ring 415 to be reciprocated.

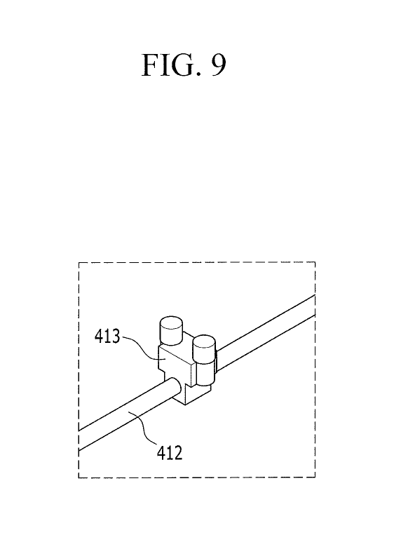

FIG. 7 illustrates the driving cam follower 413 according to an exemplary embodiment, FIG. 8 illustrates the driving camshaft 412 inserted in a plurality of driving cam followers 413 according to an exemplary embodiment, and FIG. 9 is an enlarged view of the dotted line portion of FIG. 8.

As shown in FIGS. 7 to 9, the driving camshaft 412 passes through the driving cam follower 413 of the present exemplary embodiment, and a plurality of the driving cam followers 413 are disposed along the driving camshaft 412. Each of the plurality of driving cam followers 413 may be disposed at each of a plurality of through-holes 411a formed in the driving cam plate 411, and the driving cam followers 413 may reciprocate along a boundary of the through-hole 411a formed in the first direction.

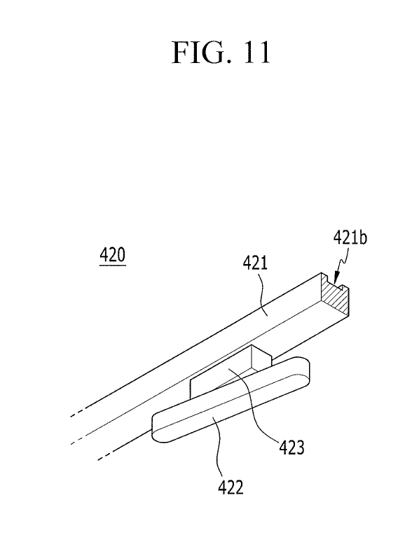

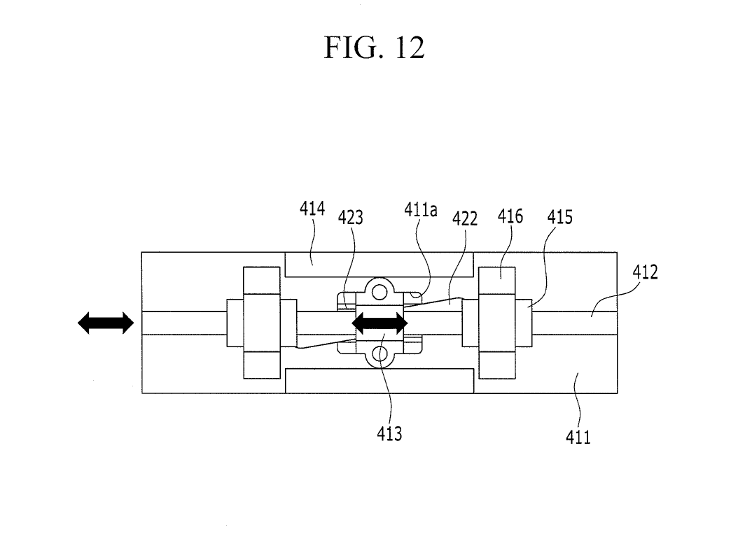

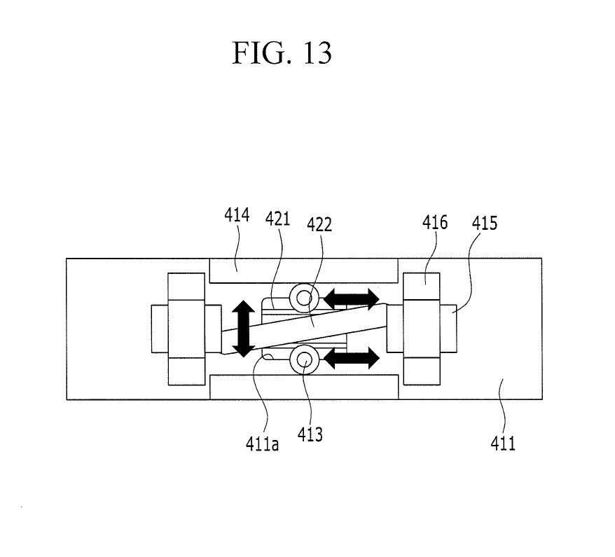

FIG. 10 illustrates the following cam unit 420 according to an exemplary embodiment, and FIG. 11 is an enlarged view of the dotted line portion of FIG. 10. FIGS. 12 and 13 illustrate schematic drawings of a movement direction changed by an interaction between the driving cam unit 410 and the following cam unit 420 according to an exemplary embodiment.

As shown in FIGS. 10 and 11, the following cam unit 420 reciprocates depending on the reciprocation direction of the driving cam unit 410 along a second direction crossing the first direction along which the driving cam unit 410 reciprocates. That is, the power that reciprocates the following cam unit 420 is transmitted from the driving cam unit 410.

The first direction according to the present exemplary embodiment may be set to be parallel to a length direction of the non-active area 24 of the mask 20 formed in a slit shape, e.g., along the y-axis in FIG. 2. Further, the second direction according to the present exemplary embodiment may be set to be perpendicular to the first direction, e.g., along the x-axis in FIG. 2, to adjust the interval of the mask fixing part 400 to correspond to a change in the interval between the non-active areas 24. Accordingly, the driving cam unit 410 reciprocates along the first direction, e.g., the driving camshaft 412 of the driving cam unit 410 may move along the y-axis, and it can change the interval between the magnets 421a included in the mask fixing part 400, e.g., along the x-axis, to correspond to the change of the interval between the non-active areas 24.

As such, in order to convert the reciprocation direction of the driving cam unit 410 in the first direction into the reciprocation direction of the following cam unit 420 in the second direction, as shown in FIGS. 10 to 13, the following cam unit 420 includes a following cam plate 421, a first following cam follower 422, and a second following cam follower 423.

As illustrated in FIG. 1, the following cam plate 421 may be attached to the driving cam plate 411, such that the following cam plate 421 and the driving camshaft 412 are on opposite surfaces of the driving cam plate 411. The magnets 421a are attached to the following cam plate 421, and are generating the magnetic force to fix the mask 20 to the following cam plate 421. As illustrated in FIG. 1, each magnet 421a is between the substrate 10 and the following cam plate 421. As illustrated in FIG. 4, the following cam plate 421 is a bar-shaped plate formed along the first direction to be parallel to and extend along the driving cam plate 411. As the driving cam unit 410 reciprocates along the first direction, the following cam plate 421 according to the present exemplary embodiment dependently reciprocates in the second direction.

Referring to FIG. 11, a magnet fixing groove 421b is formed on one surface of the following cam plate 421. As illustrated in FIGS. 2-3, the magnet 421a according to the present exemplary embodiment is a bar-shaped magnet disposed parallel to the length direction of the following cam plate 421, i.e., along the y-axis, and is inserted in and fixed to the magnet fixing groove 421b.

As further illustrated in FIG. 11, the first following cam follower 422 is obliquely disposed at an angle of about 0 to about 90 degrees from the first direction toward the second direction, so that the reciprocation direction of the driving cam unit 410 in the first direction may be changed to the reciprocation direction of the following cam unit 420 in the second direction. As shown in FIGS. 12 and 13, the first following cam follower 422 is obliquely disposed at an angle of about 0 to about 90 degrees from the first direction toward the second direction, meaning that it is disposed in an additional direction of a vector toward the first direction and a direction of a vector in the second direction, i.e., the direction of the first following cam follower 422 has a vector component in each of the first and second directions. That is, the disposed direction of the first following cam follower 422 includes both a component parallel to the first direction and a component parallel to the second direction. Accordingly, when a power parallel to the first direction is applied to the first following cam follower 422, the applied power may be changed to a power parallel to the second direction.

The second following cam follower 423 is disposed to pass through the through-hole 411a formed in the driving cam plate 411 (FIG. 4), and it fixes the first following cam follower 422 to the following cam plate 421. As such, the first following cam follower 422 and the following cam plate 421 are at opposite surfaces of the driving cam plate 411. Further, since the second following cam follower 423 connects and fixes the first following cam follower 422 and the following cam plate 421, when the first following cam follower 422 converts a direction of power transmitted from the driving cam unit 410 into the second direction, the second following cam follower 423 transmits the power transmitted from the driving cam unit 410 to the following cam plate 421. As a result, the following cam unit 420 may reciprocate in the second direction.

In this case, the second following cam follower 423 of the present exemplary embodiment may be formed to have the same width as a width of a direction parallel to the first direction of the through-hole 411a. In contrast, a width of a direction parallel to the second direction of the through-hole 411a may be wider than a width of a direction parallel to the second direction of the second following cam follower 423. That is, although the second following cam follower 423 can freely move along second direction within the through-hole 411a, it cannot move along the first direction due to being fixed with respect to the first direction.

Because of this structure, even though the first following cam follower 422 reciprocates by both the power parallel to the first direction and the power parallel to the second direction, since the second following cam follower 423 is inserted and fixed into the through-hole 411a, it cannot reciprocate along the first direction. Accordingly, the second following cam follower 423 can transmit only the power for reciprocating along the second direction to the following cam plate 421.

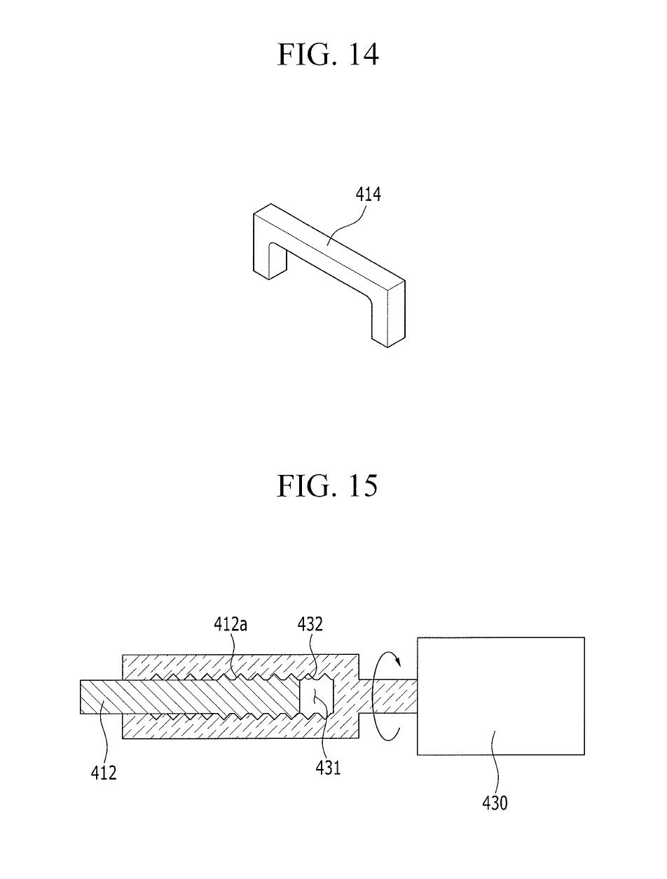

Meanwhile, the driving cam unit 410 according to an exemplary embodiment may further include a pair of driving cam guides 414. FIG. 14 illustrates the driving cam guide 414 according to the exemplary embodiment.

The driving cam guides 414 having a shape as shown in FIG. 14 are disposed parallel along the first direction, as shown in FIGS. 4, 6, 12, and 13, and they guide the driving cam follower 413 to reciprocate along the first direction. That is, the driving cam guides 414 are disposed at opposite side ends of the driving cam plate 411 along the length direction thereof so that a reciprocating path of the driving cam follower 413 may be formed. The driving cam follower 413 may reciprocate only within a range predetermined by the driving cam guides 414, and the driving cam guides 414 prevent the driving cam follower 413 from deviating from the driving cam plate 411.

Further, the driving motor 430 according to the present exemplary embodiment supplies power to the driving cam unit 410. More specifically, the driving motor 430 transmits power to the driving camshaft 412 included in the driving cam unit 410 so that the driving camshaft 412 may reciprocate along the first direction.

FIG. 15 illustrates the driving camshaft 412 inserted into the driving motor 430 according to an exemplary embodiment.

As shown in FIG. 15, an insertion hole 431 in which one end of the driving camshaft 412 may be inserted may be formed in the driving motor 430 according to the present exemplary embodiment. A first screw thread 412a may be formed on one end of the driving camshaft 412 inserted into the insertion hole 431, and a second screw thread 432 may be formed on an interior circumference of the insertion hole 431 in which the end one of the driving camshaft 412 is inserted so as to correspond to the one end of the driving camshaft 412 on which the first screw thread 412a is formed.

The driving camshaft 412 on which the first screw thread 412a is formed and the interior circumference of the insertion hole 431 on which the second screw thread 432 is formed are engaged with each other to be capable of being rotated by a screw movement. In this case, when the insertion hole 431 on which the second screw thread 432 is formed by power generated by the driving motor 430, the driving camshaft 412 on which the first screw thread 412a is formed may be moved along the first direction by the second screw thread 432 corresponding to the first screw thread 412a. That is, the driving camshaft 412 may be moved along one side of the first direction by the power of the driving motor 430.

The driving cam unit 410 and the following cam unit 420 according to the present exemplary embodiment are respectively provided in a plurality, and the driving cam units 410 and the following cam units 420 respectively consist of a pair that are integrally combined to be disposed parallel along the first direction. Respective combinations of the plurality of the driving cam units 410 and the following cam units 420 may be disposed parallel at a position corresponding to the non-active area 24 of the mask 20 to have an interval corresponding to the active area 22 of the mask 20.

When an interval between the active areas 22 of the mask 20 is changed, an interval between the following cam units 420 adjacent to each other may be narrowed or widened by moving the driving camshaft 412 along the first direction using the driving motor 430 and by the following cam unit 420 being moved along the second direction depending on the movement of the driving camshaft 412.

Accordingly, as an interval between the magnets 421a included in the following cam unit 420 is narrowed or widened, the magnets 421a are disposed to correspond to the non-active area 24 of the mask 20, such that fixation of the mask 20 may be improved.

In this case, magnetic poles of the neighboring magnets 421a may be arranged opposite from each other so that a fixing force by the magnets 421a may be greater than the force of the fixation of the mask 20. When the magnetic poles are arranged to be opposite to each other, since density of magnetic field lines mask 20 may be the highest in the non-active area 24, fixation of the mask 20 may be further improved by the magnetic force.

By way of summation and review, a mask exposing an area of the substrate is disposed on the substrate, and then material is vaporized under a vacuum atmosphere to be deposited on the substrate through the mask. However, when the mask moves or is not firmly fixed, the material may be deposited in an incorrect area of the substrate, i.e., on an area in which the deposition need not be formed. In this case, a circuit may be formed in an incorrect area of the substrate, i.e., on an area in which the circuit need not be formed, or other product defects, e.g., misalignment due to an error of the deposition area, may occur in processes to be performed later.

In contrast, the deposition apparatus 1000, according to embodiments, includes the mask fixing part 400 that may variably adjust the interval between the magnets 421a fixing the mask 20 based on the size of the mask 20. According to the present exemplary embodiment, even though the sizes of the substrate 10 and the mask 20 are changed, it is possible to adjust the interval between the magnets 421a without replacing the deposition apparatus 1000 or the mask fixing part 400.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A deposition apparatus, comprising:
a chamber maintaining a vacuum atmosphere;
a deposition material container within the chamber to contain a deposition material;
a substrate fixing part to face the deposition material container and to fix a substrate;
a mask fixing part on a first surface of the substrate, the mask fixing part including:
a plurality of magnets on the first surface of the substrate,
a driving cam unit that reciprocates along a first direction,
a following cam unit that reciprocates in a second direction crossing the first direction in accordance with a reciprocation direction of the driving cam unit, and
a driving motor to supply a predetermined power to the driving cam unit.

2. The deposition apparatus as claimed in claim 1, wherein the driving cam unit includes:
a driving cam plate including a plurality of through-holes along the first direction;
a driving camshaft connected to the driving motor and reciprocating along the first direction; and
a plurality of driving cam followers, the driving camshaft passing through the plurality of driving cam followers, and the driving cam followers reciprocating in accordance with a reciprocation direction of the driving camshaft.

3. The deposition apparatus as claimed in claim 2, wherein the following cam unit includes:
a following cam plate supporting the plurality of magnets, the following cam plate reciprocating along the second direction corresponding to the reciprocation direction of the driving cam unit;
a first following cam follower at an angle of about 0 to about 90 degrees from the first direction toward the second direction; and
a second following cam follower passing through the through-hole to fix the first following cam follower to the following cam plate.

4. The deposition apparatus as claimed in claim 3, wherein:
a width of a direction parallel to the first direction of the through-hole is equal to a width of a direction parallel to the first direction of the second following cam follower, and
a width of a direction parallel to the second direction of the through-hole is greater than that of a direction parallel to the second direction of the second following cam follower.

5. The deposition apparatus as claimed in claim 3, wherein the following cam plate includes a magnet fixing groove along the first direction, the magnet being inserted in and fixed to the magnet fixing groove.

6. The deposition apparatus as claimed in claim 2, wherein the driving cam unit includes a pair of driving cam guides along the first direction to guide the reciprocation of the driving cam follower.

7. The deposition apparatus as claimed in claim 2, wherein the driving cam plate includes:
a fixing ring, the driving camshaft being inserted into, passing through, and affixed to the fixing ring; and
a shaft guide, the fixing ring being inserted into the shaft guide to be combined with the driving cam plate.

8. The deposition apparatus as claimed in claim 2, wherein:
the driving motor includes an insertion hole, an end of the driving camshaft being inserted into the insertion hole,
a first screw thread at the end of the driving camshaft is inserted into the insertion hole, a second screw thread corresponding to the first screw thread being on an interior circumference of the insertion hole, and
when the driving motor rotates the insertion hole, the first screw thread and the second screw thread perform a screw movement, and the driving camshaft reciprocates according to the screw movement.

9. The deposition apparatus as claimed in claim 1, wherein the mask includes:
an active area opened to correspond to a deposition area in which the deposition material is deposited on the substrate; and
a non-active area blocking the deposition material from being deposited on the substrate.

10. The deposition apparatus as claimed in claim 9, wherein:
each of the driving cam unit and the following cam unit is provided in a plurality, and
the pluralities of the driving cam units and the following cam units are respectively integrally combined to be parallel at a position corresponding to the non-active area of the mask in order to have an interval corresponding to the active area of the mask.

11. The deposition apparatus as claimed in claim 10, wherein magnetic poles of neighboring magnets are arranged opposite from each other.
